(19) United States
(12) Patent Application Publication
(10) Pub. No.: US 2025/0324588 A1
(43) Pub. Date: Oct. 16, 2025

(54) MEMORY DEVICE AND METHOD FOR MANUFACTURING THE SAME

(71) Applicant: Winbond Electronics Corp., Taichung City (TW)

(72) Inventors: Tzu-Yun HUANG, Kaohsiung City (TW); Wen-Chieh TSAI, Tainan City (TW); Yu-Lung WANG, Taichung City (TW)

(21) Appl. No.: 19/169,381

(22) Filed: Apr. 3, 2025

(30) Foreign Application Priority Data
Apr. 16, 2024 (TW) 113114137

(51) Int. Cl. H10B 41/35; H01L 21/762; H01L 21/764

(52) U.S. Cl. CPC H10B 41/35; H01L 21/76224; H01L 21/764

(57) ABSTRACT

A method of manufacturing a memory device includes: providing a substrate, forming a select gate structure and word line structures on the substrate, and forming a filling material to cover the select gate structure and the word line structures. The method includes etching back the filling material to expose the top of the select gate structure and the top of the word line structures, sequentially forming a cap layer and a first dielectric layer over the substrate, and etching back the first dielectric layer and the cap layer to expose the filling material between the select gate structure and the dummy word line in the word line structures that is closest to the select gate structure. The method includes removing the filling material and leaving the protruding portion of the cap layer, and forming a second dielectric layer to cover the first dielectric layer.

### CROSS REFERENCE TO RELATED APPLICATIONS

This Application claims priority of Taiwan Patent Application No. 113114137 filed on Apr. 16, 2024, the entirety of which is incorporated by reference herein.

### BACKGROUND OF THE INVENTION

### Field of the Invention

The present disclosure relates to semiconductor techniques, and in particular to a memory device and a method for manufacturing the same.

### Description of the Related Art

In the current process of forming a memory device (e.g., flash memory), the margin of the process is reduced since the dimensions of the components are continuously being scaled down. For example, after forming a select gate structure and a plurality of word line structures, a dielectric layer is generally formed to cover and form an air gap between the word line structures and/or between the select gate structure and the word line structures. Although the designs may vary depending on requirements, an excessive or high air gap between the select gate structure and the word line structures may affect the performance due to the number of defects, or it may reduce the overall structural strength, which may have undesirable effects on the memory device and cause electrical problems. Therefore, the industry still needs to improve the method of manufacturing memory devices to achieve the desired goal of maintaining the memory device yield and manufacturing progress.

### BRIEF SUMMARY OF THE INVENTION

An embodiment of the present disclosure provides a method for manufacturing a memory device, including providing a substrate, forming a select gate structure and a plurality of word line structures on the substrate, and forming a filling material to cover the select gate structure and the word line structures and to fill a space in between the select gate structure and the word line structures. The method further includes etching back the filling material to expose a top of the select gate structure and a top of the word line structures, sequentially forming a cap layer and a first dielectric layer over the substrate, and etching back the first dielectric layer and the cap layer to expose the filling material between the select gate structure and the dummy word line in the word line structures that is closest to the select gate structure. The method further includes removing the filling material, wherein the cap layer is remaining on the opposite sides of the select gate structure and the side of the dummy word line that faces the select gate structure and forms a protruding portion, and forming a second dielectric layer to fill a space in between the select gate structure and the dummy word line and to cover the first dielectric layer over the word line structures.

Another embodiment of the present disclosure provides a memory device, including a substrate, a select gate structure disposed on the substrate, and a plurality of word line structures disposed on the substrate and adjacent to the select gate structure. The memory device further includes a cap layer covering the select gate structure and each of the word line structures, and a dielectric layer filled between the select gate structure and the dummy word line in the word line structures that is closest to the select gate structure and covering the word line structures. The cap layer has a protruding portion on opposite sides of the select gate structure and the side of the dummy word line that faces the select gate structure.

### BRIEF DESCRIPTION OF THE DRAWINGS

In order to make the features and advantages of the present disclosure more obvious and easier to understand, different embodiments of the present disclosure, along with the figures, are described in detail as follows:

FIGS. 1 to 10 illustrate cross-sectional views of intermediate stages for manufacturing the memory device, in accordance with the embodiments of the present disclosure.

### DETAILED DESCRIPTION OF THE INVENTION

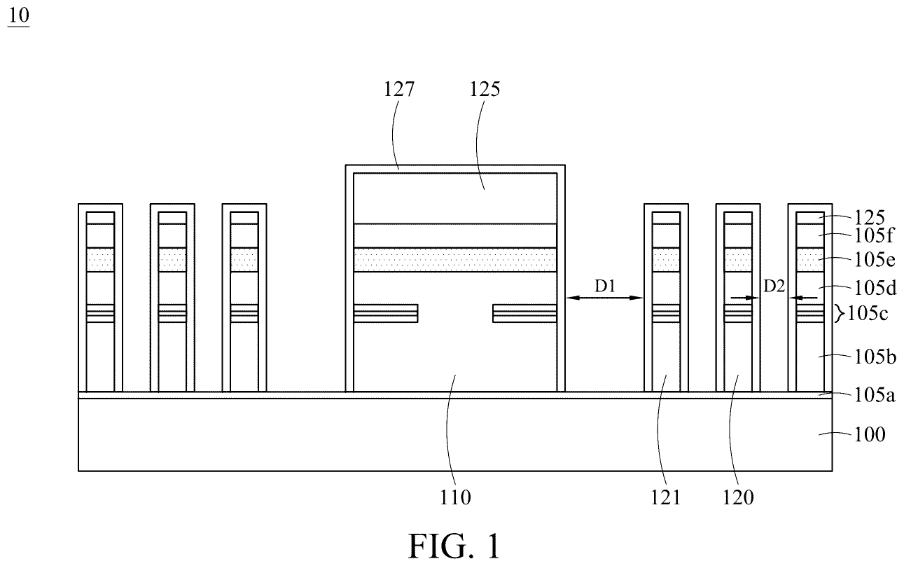

Referring first to FIG. 1. A substrate 100 is provided. In some embodiments, the substrate 100 may be an elemental semiconductor substrate, a compound semiconductor substrate, or an alloy semiconductor substrate. In other embodiments, the substrate 100 may be a semiconductor-on-insulator (SOI) substrate. The semiconductor-on-insulator substrate may include a base plate, a buried oxide (BOX) layer disposed on the base plate, and a semiconductor layer disposed on the buried oxide layer.

Still referring to FIG. 1, a select gate structure 110 and a plurality of word line structures 120 are formed on the substrate 100. The select gate structure 110 and the word line structures 120 may be formed by deposition processes combined with one or more photolithography processes and etching processes. The select gate structure 110 and the word line structures 120 may each include stacked layers, and may sequentially include from bottom to top, for example, a tunnel dielectric layer 105a, a floating gate layer 105b, an inter-gate dielectric layer 105c, a control gate layer 105d, a metal layer 105e, and a top capping layer 105f. In some embodiments, the material of the tunnel dielectric layer 105a may be silicon oxide. In some embodiments, the material of the floating gate layer 105b may be a conductive material, such as doped polysilicon, undoped polysilicon, or a combination thereof. In some embodiments, the inter-gate dielectric layer 105c may be a composite layer constructed by, for example, oxide/nitride/oxide (ONO), but the present disclosure is not limited to it, and the composite layer may also be films of five or more layers. In some embodiments, the material of the control gate layer 105d may be a conductive material, such as doped polysilicon, undoped polysilicon, or a combination thereof. In some embodiments, the material of the metal layer 105e may be such as W, TiN, or a combination thereof. In some embodiments, the material of the top capping layer 105f may be a dielectric material, such as silicon nitride, silicon oxynitride, or a combination thereof.

In some embodiments, the top surface of the select gate structure 110 is level with the top surface of the word line structures 120. In some embodiments, the distance D1 between the select gate structure 110 and the dummy word line 121 in the word line structures 120 closest to the select gate structure 110 is greater than the spacing D2 between the word line structures 120. In some embodiments, after forming the select gate structure 110 and forming the word line structures 120, a hard mask layer 125 may be remained over both of the select gate structure 110 and the word line structures 120, which has not yet been completely removed. The hard mask layer 125 may have different thicknesses over the select gate structure 110 and over the word line structures 120 due to variations of etching loading effect. In some embodiments, the hard mask layer 125 may be a single layer structure or a multi-layer structure. In some embodiments, the material of the hard mask layer 125 includes polycrystalline silicon.

A liner layer 127 is then conformally formed over the substrate 100. The liner layer 127 covers the sidewalls of the select gate structure 110, the sidewalls of the word line structures 120, and the sidewalls and the top surface of the hard mask layer 125. The liner layer 127 further protects the select gate structure 110 and the word line structures 120 from oxidation or subsequent processes.

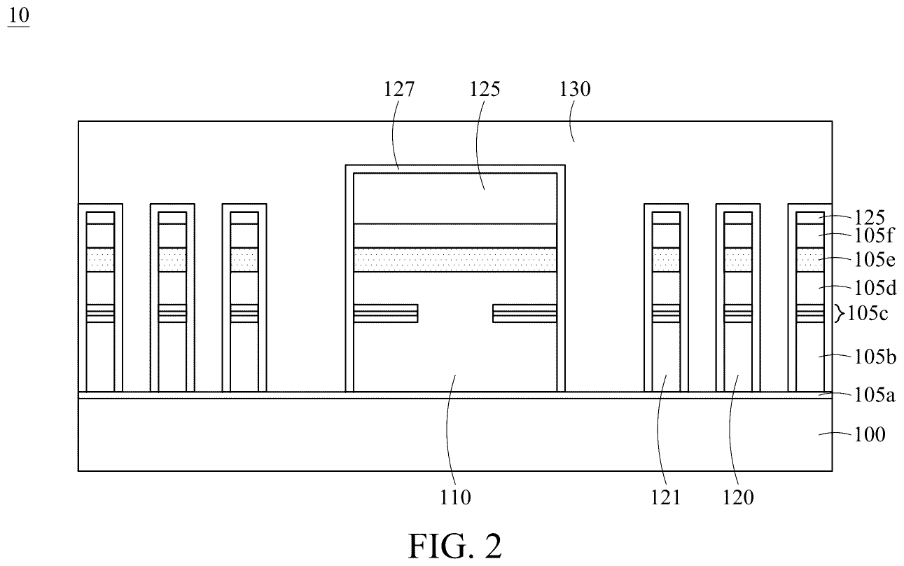

Referring next to FIG. 2. After forming the select gate structure 110 and the word line structures 120, a filling material 130 is formed to cover the select gate structure 110 and the word line structures 120 and is filled between the select gate structure 110 and the word line structures 120. The filling material 130 is temporarily filled between the select gate structure 110 and the word line structures 120 and will be removed in the subsequent process. In some embodiments, the filling material 130 may include a fluid material which helps fill the gaps between the select gate structure 110 and the word line structures 120 or between each of the word line structures 120. In some embodiments, after forming the filling material 130, a curing process may further be performed on the filling material 130 to facilitate the subsequent etching process. In some embodiments, the filling material 130 may be spin-on-carbon (SoC) or photoresist.

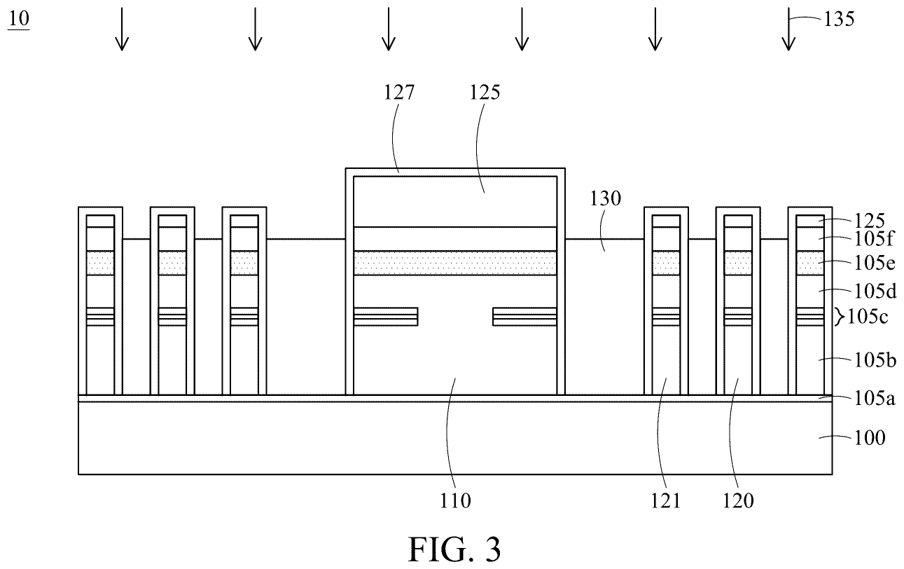

Referring next to FIG. 3. An etching back process 135 is performed on the filling material 130 such that the top surface of the filling material 130 is below the top surfaces of the select gate structure 110 and the word line structures 120. In some embodiments, the etching back process 135 may include an anisotropic etching process (or directional etching process), such as a dry etching process.

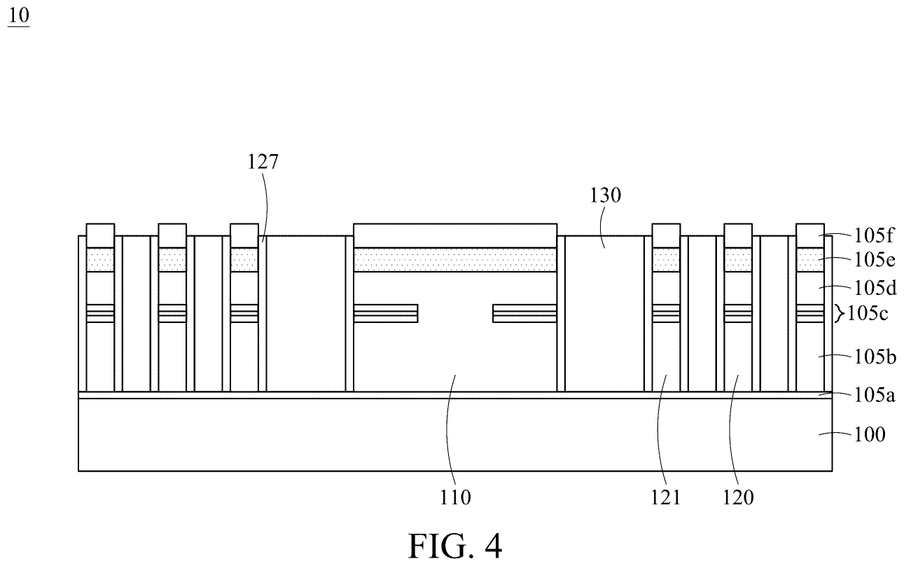

Referring to FIG. 4. The etching back process 135 may further remove the hard mask layer 125 formed over the select gate structure 110 and the word line structures 120, thereby exposing the top portion of the select gate structure 110 and the top portion of the word line structures 120. During the removal of the hard mask layer 125, the etching back process 135 also removes a portion of the liner layer 127 and exposes a portion of the sidewalls of the select gate structure 110 and the word line structures 120.

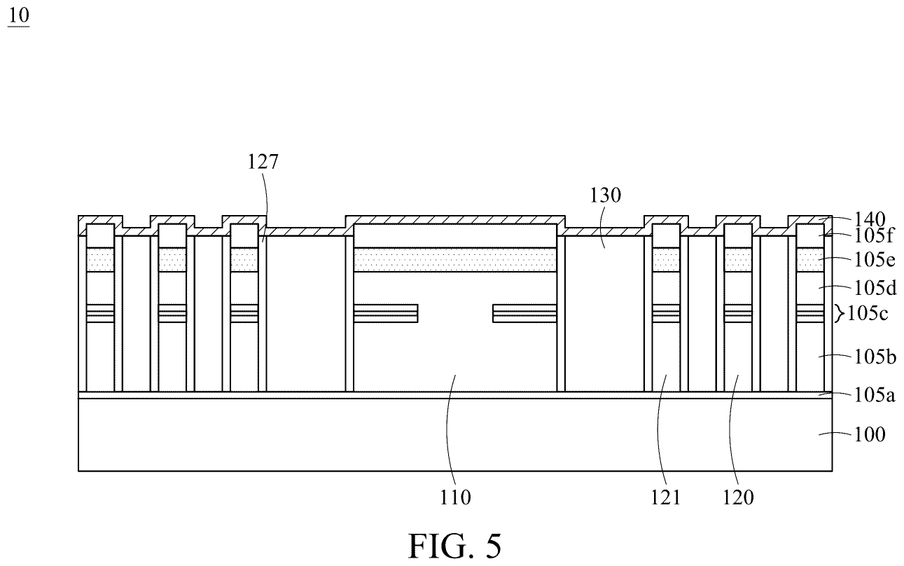

Referring next to FIG. 5. A cap layer 140 is formed over the substrate 100. In some embodiments, the cap layer 140 is conformally formed on the substrate 100, and the cap layer 140 is formed by a better step coverage process. In this way, the cap layer 140 may uniformly cover the top and a portion of the sidewalls of the select gate structure 110 and cover the top and a portion of the sidewalls of the word line structures 120 which are exposed after performing the etching back process 135. The cap layer 140 is used to define the dimensions as well as the boundaries of related air gaps (e.g., the first air gap 160) that are subsequently formed, as will be described in more detail hereinafter. In some embodiments, the cap layer 140 may be formed by a chemical vapor deposition (CVD) process, a physical vapor deposition (PVD) process, an atomic layer deposition (ALD) process, or a combination thereof. In some embodiments, the material of the cap layer 140 includes nitride, such as SiN or another suitable material.

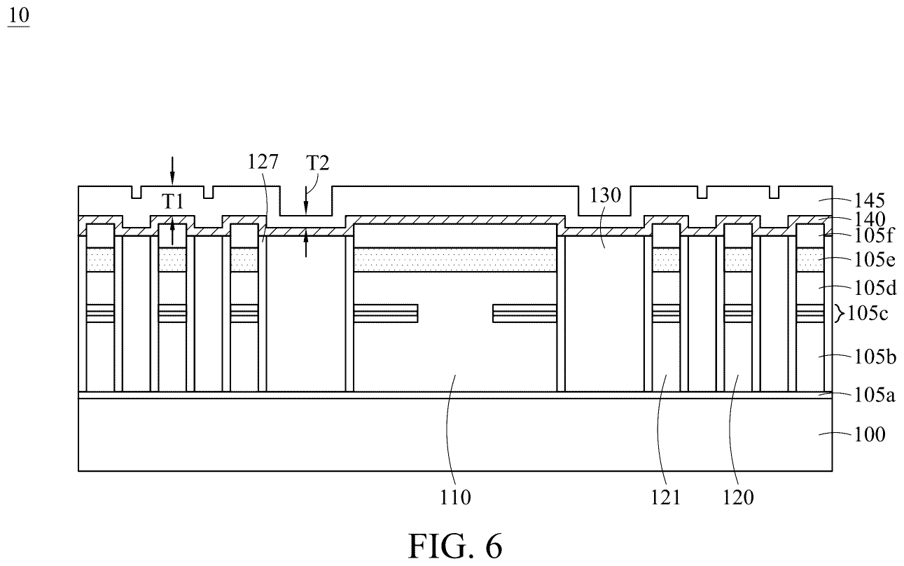

Referring next to FIG. 6. A first dielectric layer 145 is formed over the substrate 100. The first dielectric layer 145 is conformally formed on the substrate 100, such as conformally formed on the cap layer 140, and the first dielectric layer 145 is formed by a poorer step coverage process. In this way, the first dielectric layer 145 may have different thicknesses on the cap layer 140. Forming the first dielectric layer 145 with different thicknesses allows the subsequent etching back process to further etch the cap layer 140 at specific locations, as will be described in more detail hereinafter. In some embodiments, the poorer step coverage process may include a physical vapor deposition (PVD) process and a chemical vapor deposition (CVD) process. In some embodiments, the thickness T1 of the first dielectric layer 145 over the word line structures 120 is greater than the thickness T2 of the first dielectric layer 145 over the filling material 130 between the select gate structure 110 and the dummy word line 121. In some embodiments, the material of the first dielectric layer 145 may include an oxide such as tetraethylorthosilicate (TEOS) or methylsilane (silane).

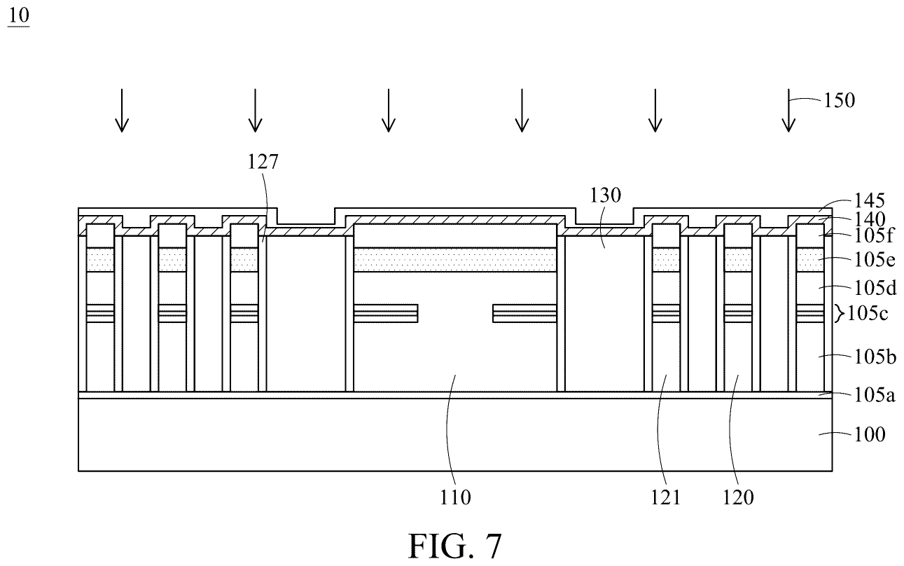

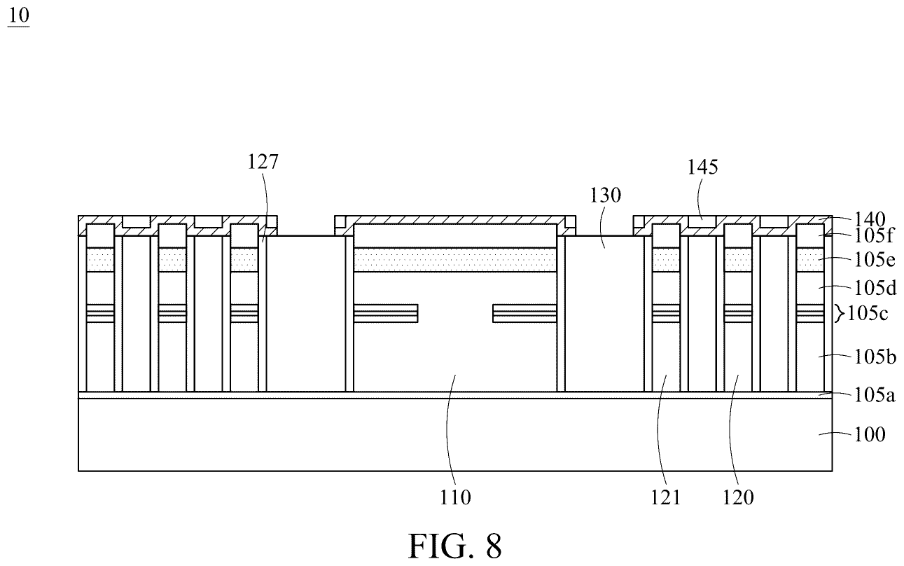

Referring next to FIGS. 7 and 8. An etching back process 150 is performed to etch the first dielectric layer 145 and the cap layer 140, and to expose the filling material 130 between the select gate structure 110 and the dummy word line 121. More specifically, as shown in FIG. 7, the etching back process 150 first removes a portion of the first dielectric layer 145. Due to the difference in thickness of the first dielectric layer 145, the first dielectric layer 145 over the filling material 130 between the select gate structure 110 and the dummy word line 121 is nearly completely removed, while the first dielectric layer 145 still remains over the word line structures 120 with a certain thickness. Subsequently, as shown in FIG. 8, the etching back process 150 further removes the first dielectric layer 145 and the cap layer 140 over the filling material 130 between the select gate structure 110 and the dummy word line 121, and exposes the top surface of the filling material 130 between the select gate structure 110 and the dummy word line 121. In some embodiments, as shown in FIG. 8, since the first dielectric layer 145 has a difference in thickness, the cap layer 140 and the first dielectric layer 145 are still remained on the top of the word line structures 120 after the etching back process 150 is performed. In other words, after the etching back process 150 is performed, the filling material 130 between the select gate structure 110 and the dummy word line 121 is exposed, while the filling material 130 between the word line structures 120 is still covered by the cap layer 140 and the first dielectric layer 145. In addition, it should be noted that although the etching back process 150 removes the first dielectric layer 145 and the cap layer 140 over the filling material 130 between the select gate structure 110 and the dummy word line 121, the cap layer 140 and the first dielectric layer 145 are still remained on the opposite sides of the select gate structure 110 and on the side of the dummy word line 121 toward the select gate structure 110 due to structural differences. In some embodiments, the etching back process 150 may include an anisotropic etching process (or a directional etching process), such as a dry etching process.

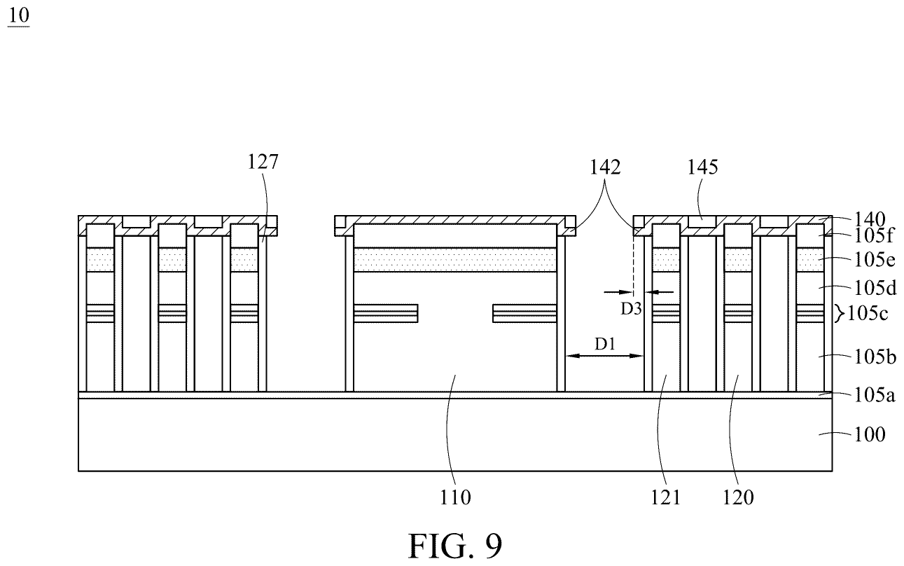

Referring next to FIG. 9. The filling material 130 is removed such that the word line structures 120 do not have any filling material 130 between each of the word line structures 120. In some embodiments, the cap layer 140 is remaining on the opposite sides of the select gate structure 110 and on the side of the dummy word line 121 toward the select gate structure 110 and forms a protruding portion 142. That is, due to the difference in thicknesses of the first dielectric layer 145, the cap layer 140 on the opposite sides of the select gate structure 110 and on the side of the dummy word line 121 toward the select gate structure 110 is not completely removed by the etching back process 150 and becomes the protruding portion 142 after the removal of the filling material 130. In some embodiments, the filling material 130 may be removed by a wet etching process or an ashing process. In some embodiments, the cap layer 140 still covers the top surface and a portion of the sidewalls of each of the word line structures 120 to form a hat-shaped structure. In some embodiments, the hat-shaped structure over each of the word line structures 120 are connected to each other. In some embodiments, the ratio of the protruding distance D3 of the protruding portion 142 of the cap layer 140 to the distance D1 between the select gate structure 110 and the dummy word line 121 in the word line structures 120 is in a range of 0.1 to 0.25.

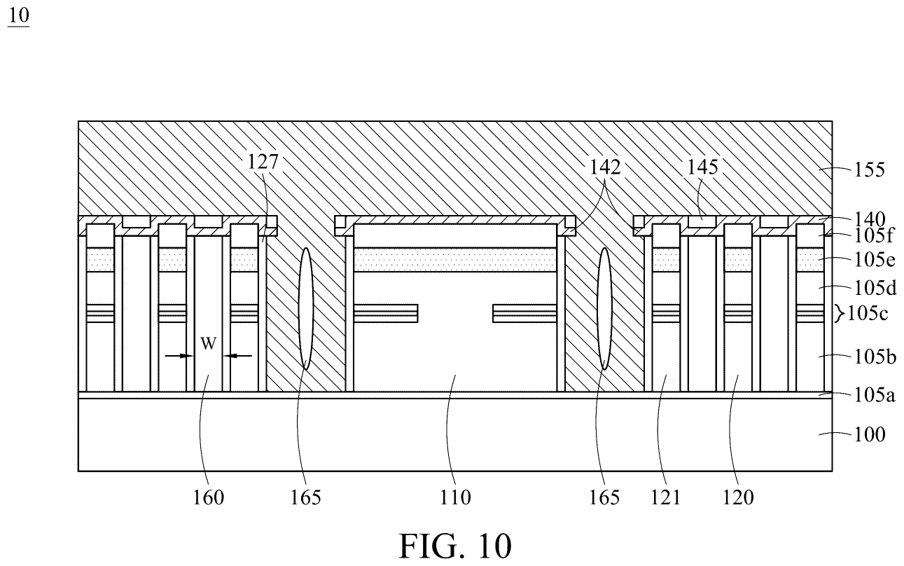

Referring next to FIG. 10. A second dielectric layer 155 is formed to fill the space in between the select gate structure 110 and the dummy word line 121 and to cover the first dielectric layer 145 and the cap layer 140 over the word line structures 120. A first air gap 160 is formed between the word line structures 120, and the first air gap 160 is separated from the second dielectric layer 155 by the cap layer 140 and the first dielectric layer 145. In other words, the filling material 130 reserves a space for the first air gap 160, and the first air gap 160 is formed after the filling material 130 is removed and the second dielectric layer 155 is formed. In this way, the dimension of the first air gap 160 may be ensured such that the first air gap 160 does not form as a hammered shape, but rather maintains the original shape between the word line structures 120. In some embodiments, the width W of the first air gap 160 is equal to the spacing D2 between the word line structures. In addition, in some embodiments, the second dielectric layer 155 further forms a second air gap 165 between the select gate structure 110 and the dummy word line 121, and the first air gap 160 is greater than the second air gap 165. Accordingly, it may be ensured that the overall structure of the memory device 10 is not affected by the large second air gap 165, which may affect its structural strength. In some embodiments, the material of the second dielectric layer 155 may include an oxide such as tetraethylorthosilicate (TEOS) or methylsilane (silane).

After forming the second dielectric layer 155, other semiconductor processes may be continued to form various elements and components of the memory device 10 (e.g., flash memory), such as various elements and components of NAND flash memory, which will not be described herein.

In summary, the embodiments of the present disclosure may effectively maintain the dimension of the air gap between the word line structures by combining the formation of the filling material and the cap layer. At the same time, the air gap between the word line structures may be minimized and the strength of the structure may be maintained, thereby maintaining the yield of the memory device. In addition, the hat-shaped cap layer formed on the word line structures also helps to enhance the structural stability of the word line structures.

One aspect of the present disclosure provides a method for manufacturing a memory device, including providing a substrate, forming a select gate structure and a plurality of word line structures on the substrate, and forming a filling material to cover the select gate structure and the word line structures and to fill the space in between the select gate structure and the word line structures. The method further includes etching back the filling material to expose a top of the select gate structure and a top of the word line structures, sequentially forming a cap layer and a first dielectric layer over the substrate, and etching back the first dielectric layer and the cap layer to expose the filling material between the select gate structure and the dummy word line in the word line structures that is closest to the select gate structure. The method further includes removing the filling material, wherein the cap layer is remaining on the opposite sides of the select gate structure and the side of the dummy word line that is facing the select gate structure and forms a protruding portion, and forming a second dielectric layer to fill the space in between the select gate structure and the dummy word line and to cover the first dielectric layer over the word line structures.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

What is claimed is:

1. A method for manufacturing a memory device, comprising:
providing a substrate;
forming a select gate structure and a plurality of word line structures on the substrate;
forming a filling material to cover the select gate structure and the word line structures and to fill in between the select gate structure and the word line structures;
etching back the filling material to expose a top of the select gate structure and a top of the word line structures;
sequentially forming a cap layer and a first dielectric layer over the substrate;
etching back the first dielectric layer and the cap layer to expose the filling material between the select gate structure and a dummy word line in the word line structures closest to the select gate structure;
removing the filling material, wherein the cap layer is remaining on opposite sides of the select gate structure and a side of the dummy word line toward the select gate structure and forms a protruding portion; and
forming a second dielectric layer to fill in between the select gate structure and the dummy word line and to cover the first dielectric layer over the word line structures.

2. The method as claimed in claim 1, wherein a first air gap is between the word line structures, and the first air gap is separated from the second dielectric layer by the cap layer and the first dielectric layer.

3. The method as claimed in claim 2, wherein a second air gap in the second dielectric layer is between the select gate structure and the dummy word line, and the first air gap is larger than the second air gap.

4. The method as claimed in claim 1, wherein a top surface of the select gate structure is level with a top surface of the word line structures.

5. The method as claimed in claim 1, wherein a distance between the select gate structure and the dummy word line in the word line structures is greater than a spacing between the word line structures.

6. The method as claimed in claim 1, wherein the filling material is spin-on-carbon or photoresist.

7. The method as claimed in claim 1, wherein the cap layer and the first dielectric layer are conformally formed on the substrate, wherein the cap layer is formed by a better step coverage process, and the first dielectric layer is formed by a poorer step coverage process.

8. The method as claimed in claim 7, wherein a thickness of the first dielectric layer over the word line structures is greater than a thickness of the first dielectric layer over the filling material between the select gate structure and the dummy word line.

9. The method as claimed in claim 1, wherein the cap layer covers a top surface and a portion of sidewalls of each of the word line structures to form a hat-shaped structure over each of the word line structures.

10. The method as claimed in claim 9, wherein the hat-shaped structure over each of the word line structures are connected to each other.

11. A memory device, comprising:
a substrate;
a select gate structure disposed on the substrate;
a plurality of word line structures disposed on the substrate and adjacent to the select gate structure;
a cap layer covering the select gate structure and each of the word line structures; and
a dielectric layer filled between the select gate structure and a dummy word line in the word line structures closest to the select gate structure and covering the word line structures,
wherein the cap layer has a protruding portion on opposite sides of the select gate structure and a side of the dummy word line toward the select gate structure.

12. The memory device as claimed in claim 11, wherein a first air gap is between the word line structures, and the first air gap is separated from the dielectric layer by the cap layer.

13. The memory device as claimed in claim 12, wherein a second air gap in the dielectric layer is between the select gate structure and the dummy word line, and the first air gap is greater than the second air gap.

14. The memory device as claimed in claim 12, wherein a width of the first air gap is equal to a spacing between the word line structures.

15. The memory device as claimed in claim 11, wherein the cap layer covers a top surface and a portion of sidewalls of each of the word line structures to form a hat-shaped structure over each of the word line structures.

16. The memory device as claimed in claim 15, wherein the hat-shaped structure over each of the word line structures is connected to each other.

17. The memory device as claimed in claim 11, wherein a top surface of the select gate structure is level with a top surface of the word line structures.

18. The memory device as claimed in claim 11, wherein a distance between the select gate structure and the dummy word line in the word line structures is greater than a spacing between the word line structures.

19. The memory device as claimed in claim 11, wherein a material of the cap layer comprises nitride.

20. The memory device as claimed in claim 11, wherein a ratio of a protruding distance of the protruding portion of the cap layer to a distance between the select gate structure and the dummy word line in the word line structures is in a range of 0.1 to 0.25.
